(19) United States
(12) Patent Application Publication
(10) Pub. No.: US 2010/0259876 A1
(43) Pub. Date: Oct. 14, 2010

(54) STAND HINGE FOR AN ELECTRONIC DEVICE AND AN ELECTRONIC DEVICE WITH SAME

(75) Inventor: Chang Soo Kim, Gyeonggi-do (KR)

Correspondence Address: HARNESS, DICKEY, & PIERCE, P.L.C, 7700 Bonhomme, Suite 400, ST. LOUIS, MO, 63105, US

(73) Assignee: Laird Technologies Korea YH, Bucheon-si, Gyeonggi-do (KR)

(21) Appl. No.: 12/738,828

(22) PCT Filed: Oct. 23, 2008
(86) PCT No.: PCT/KR08/06272

§ 371 Date: Jun. 8, 2010

(30) Foreign Application Priority Data
Oct. 24, 2007 (KR) 10-2007-0107097

(51) Int. Cl. H05K 7/00; F16M 11/06

(52) U.S. Cl. 361/679.01; 248/121

(57) ABSTRACT

The present invention provides a stand hinge for an electronic device, which is capable of standing an electronic device at different angles and positions. The present invention further provides an electronic device equipped with the same. The stand hinge of the present invention includes: a connecting member hinge-jointed to an electronic device to rotate in a first direction; and a supporting member for supporting the electronic device against a surface, the supporting member being hinge-jointed to the connecting member to rotate in a second direction different from the first direction.

### TECHNICAL FIELD

The present invention generally relates to a stand hinge for an electronic device, and more particularly to a stand hinge for an electronic device that is rotatable at different angles in order to support the same. Further, the present invention relates to an electronic device equipped with the above stand hinge.

### BACKGROUND ART

Various electronic devices such as DMB (Digital Multimedia Broadcasting) terminals, PMPs (Portable Multimedia Players), portable terminals, etc., which have convenient portability and provide much data by means of an image output device, have been recently introduced in the art.

In particular, the portable terminals have gained great popularity since they provide additional functions (e.g., watching TV or movies or taking photos, etc.) in addition to their inherent mobile communication function.

In order to watch the data from such electronic devices, the image output device of the electronic device must be maintained at appropriate angles so that users can see the image output device well. To this end, the electronic device must stay fixed as directly held in a user's hand. Otherwise, it must be leaned against a structure such as a wall. In case the user holds the electronic device in his/her hand, the user cannot maintain such a posture for a long time due to a burden imposed on his/her shoulder or wrist. Further, leaning the electronic device against a wall is often restricted. Thus, there is a great inconvenience in using the electronic device.

Accordingly, the electronic device is equipped with a stand hinge, which allows the electronic device to stand anywhere for a long time. Generally, a conventional stand hinge for an electronic device is attached to a back side of an image output device and folds down when it is not used. When in use, however, its stand folds out and becomes fixed in order to support the electronic device.

FIG. 1 is a perspective view showing a conventional stand hinge for an electronic device. As shown in FIG. 1, there is provided an electronic device 20 having a stand 30 hinge-jointed to its lateral sides 22, 23.

A display device 21 is provided at a front side of the electronic device 20.

The stand 30 has a ‘U’ shape and includes a hinge 31 at each end. The stand is configured to be rotatably coupled to the lateral sides 22, 23 of the electronic device 20.

FIG. 2 is an enlarged perspective view of portion III of FIG. 1.

A step 24 is formed at each of the lateral sides 22, 23 so as to be located at a same height. The step 24 is comprised of a raised portion 25 and a flat portion 26.

The U-shaped stand 30 is coupled to the flat portion 26 using the hinge 31 and rotates via the hinge 31 by almost 90 degrees relative to the raised portion 25. The U-shaped stand 30 stops when it is brought into contact with the raised portion 25 during a rotation around the hinge 31.

The operations of the above-described stand 30 are described below. First, the stand 30 is rotated and supported by the raised portion 25. Thereafter, the stand 30 is brought into contact with a surface and the electronic device 20 forms a certain angle with the surface. In such a case, since the stand 30 is fixed as supported by the raised portion 23, the electronic device 20 can stand in a stable manner.

When not in use, the stand 30 is rotated and positioned with respect to the lateral sides of the electronic device 20. As such, the electronic device 20 provides convenient portability and can further eliminate any inconvenience associated with separate carrying. However, since an angle between the electronic device 20 and the surface is predetermined (i.e., the electronic device 20 is supported as the stand 30 is rotated at a predetermined angle, e.g., 90 degrees), the electronic device 20 fails to stand at different angles.

In addition, there is a drawback in that the electronic device 20 becomes large in volume due to the U-shaped stand 30 attached thereto.

### DISCLOSURE

### Technical Problem

The present invention is devised in order to solve the foregoing problems. The present invention provides a stand hinge for an electronic device, which is capable of standing an electronic device at different angles while minimizing a size of the electronic device. The present invention further provides an electronic device with such a stand hinge mounted thereto.

### Technical Solution

In order to achieve the above object, a stand hinge for an electronic device according to the present invention may be as described below.

A stand hinge for an electronic device of the present invention comprises a connecting member hinge jointed to an electronic device to rotate in a first direction; and a supporting member for supporting the electronic device against a surface, wherein the supporting member is hinge jointed to the connecting member to rotate in a second direction different from the first direction.

The connecting member is rotated perpendicularly to the electronic device, while the supporting member is rotated perpendicularly to a rotating direction of the connecting member.

The connecting member or the supporting member is semi-automatically rotated.

The connecting member or the supporting member is stepwise rotated for angle adjustment.

The stand hinge further comprises a base that is inserted into the electronic device. The connecting member is hinge-jointed to the base. A stop protrusion is formed at one end of the connecting member hinge-jointed to the base to semi-automatically rotate. A friction member and an elastic member are inserted into the base. The friction member is in contact with the stop protrusion at one side thereof and restricts a rotation of the connecting member. The elastic member is in contact with an opposite side of the friction member and applies an elastic force to the friction member.

One surface of the stop protrusion is in contact with the friction member to prevent the rotation of the connecting member, while the other surface of the stop protrusion adjoining the one surface is brought into contact with the friction member after the rotation of the connecting member to stop the rotation of the connecting member.

An engagement groove is formed at an opposite end of the connecting member joined to the supporting member to perform stepwise rotations. An engaging member and an elastic member are inserted into the supporting member. The engaging member is formed at one side thereof with an engagement protrusion being inserted into the engagement groove. The elastic member is in contact with an opposite side of the engaging member in order to elastically support the engaging member.

An electronic device equipped with a stand hinge of the present invention comprises a stand hinge for supporting the electronic device. The stand hinge includes: a connecting member hinge-jointed to an electronic device to rotate in a first direction; and a supporting member for supporting the electronic device against a surface, wherein the supporting member is hinge-jointed to the connecting member to rotate in a second direction different from the first direction. A stand groove, to which the stand hinge is inserted, is formed at the electronic device.

The electronic device equipped with a stand hinge of the present invention further comprises a base that is inserted into the electronic device. The stand groove is linearly formed such that the base, the connecting member and the supporting member are inserted therein.

### ADVANTAGEOUS EFFECTS

As described above, the stand hinge for an electronic device of the present invention can be adjusted to different angles since the connecting member and the supporting member are rotated in different directions.

Further, the connecting member and the supporting member are rotated perpendicularly to each other, thereby providing easy angle adjustment and convenient use.

Also, the connecting member or the supporting member is semi-automatically rotated, thereby providing a simple operation method and convenient use.

Additionally, the connecting member or the supporting member is stepwise rotated, thereby allowing the stand hinge to be adjusted at different angles.

Furthermore, since the friction member is in contact with the stop protrusion while being elastically supported by the elastic member, the connecting member can be semi-automatically rotated.

Since the stop protrusion is contacted to the friction member to fix the connecting member, the electronic device can stand in a stable manner.

Moreover, the engaging member and the engagement grooves allow the supporting member to stop at different angles.

Since the stand groove is formed at the electronic device, the electronic device has a simple appearance and becomes small in size.

Further, the linear stand groove facilitates and simplifies the arrangement of the stand hinge.

### DESCRIPTION OF DRAWINGS

FIG. 1 is a perspective view showing a conventional stand hinge for an electronic device.

FIG. 2 is an enlarged perspective view of portion III of FIG. 1.

FIG. 3 is a perspective view of a stand hinge for an electronic device according to one embodiment of the present invention.

FIG. 4 is an exploded perspective view of a stand hinge for an electronic device according to one embodiment of the present invention.

FIG. 5 is an exploded perspective view of an electronic device with a stand hinge according to one embodiment of the present invention.

FIGS. 6 to 8 show operations of a stand hinge taken along the line A-A of FIG. 3.

FIGS. 9 to 11 show operations of a stand hinge taken along the line B-B of FIG. 3.

FIGS. 12 to 14 show operations of an electronic device with a stand hinge according to one embodiment of the present invention.

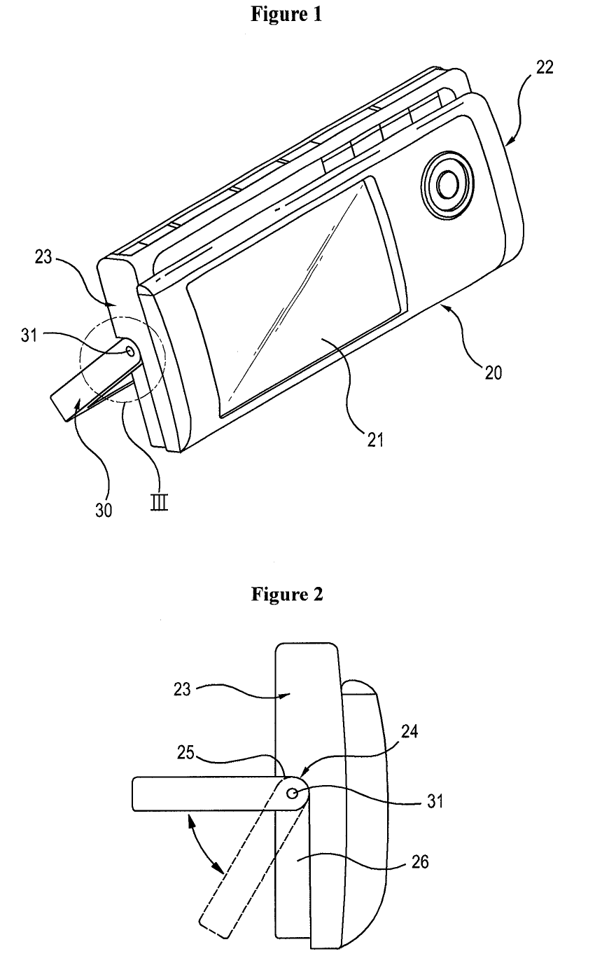

### MODE FOR INVENTION

A preferred embodiment of the present invention will now be described in detail with reference to the accompanying drawings.

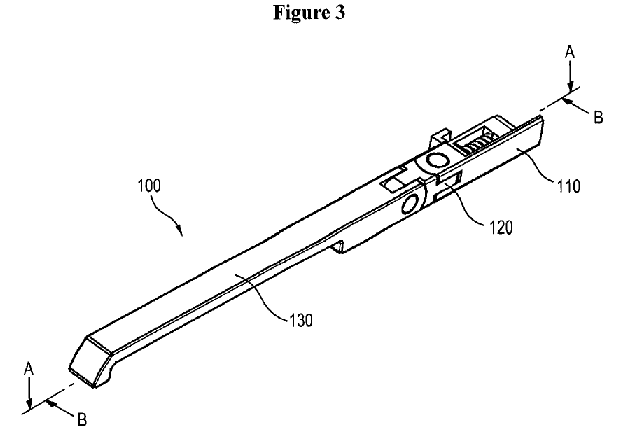

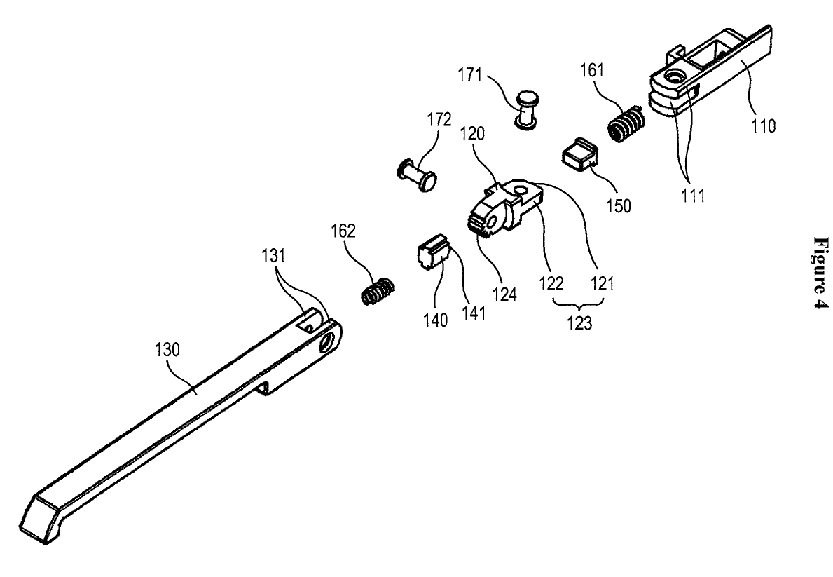

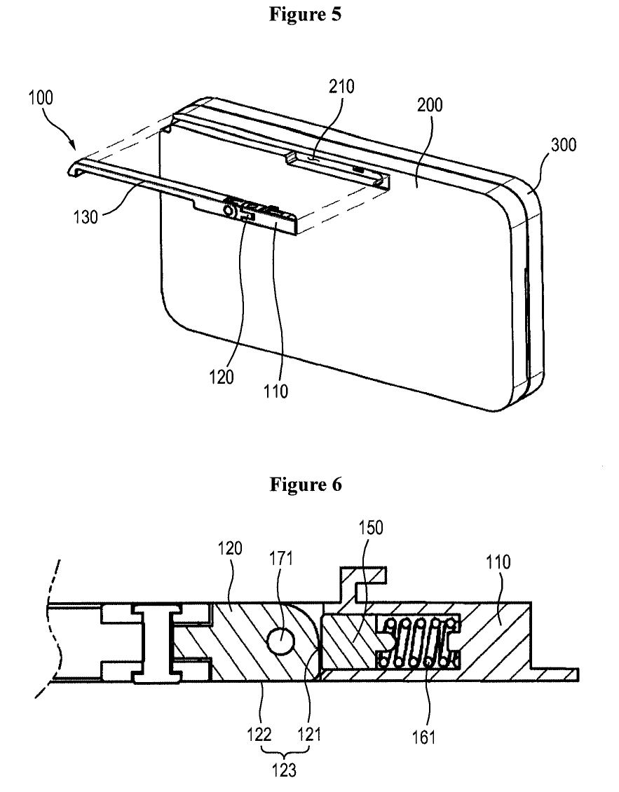

FIG. 3 is a perspective view of a stand hinge for an electronic device according to one embodiment of the present invention. FIG. 4 is an exploded perspective view of a stand hinge for an electronic device according to one embodiment of the present invention. FIG. 5 is an exploded perspective view of an electronic device with a stand hinge according to one embodiment of the present invention.

As shown in FIGS. 3 and 4, a stand hinge for an electronic device 100 of the present invention comprises a base 110, a connecting member 120, a supporting member 130, an engaging member 140 and a friction member 150.

The base 110 has an internal space formed therein. First shaft supports 111 are bilaterally formed at one side of the base. The first shaft supports 111 define a space therebetween, which communicates with the internal space of the base 110.

The base 110 may be integrally formed to an electronic device in order to decrease the size of the stand hinge 100. In this embodiment, the base is provided separately. The base 110, which is provided separately from the electronic device, is fixedly mounted to the electronic device.

A stop protrusion 123 is formed at the connecting member 120 and protrudes toward the base 110 parallel to the first shaft supports 111. The stop protrusion 123 is inserted between the first shaft supports 111 and joined thereto to rotate about a first rotating shaft 171.

The stop protrusion 123 has a sloped surface 121 located opposite to the base 110 and a straight surface 122, which is angled at an angle of about 90 degrees with respect to the sloped surface 121 and adjoins the sloped surface. Before rotation of the connecting member 120, the sloped surface 121 contacts the friction member 150 to stop the connecting member 120. When the connecting member 120 rotates, the straight surface 133 adjoining the sloped surface 121 is brought into contact with the friction member 150 to thereby stop the rotation of the connecting member 120. In addition, an intersection between the sloped surface 121 and the straight surface 122 is rounded. This allows a smooth rotation during the rotation of the connecting member 120.

The friction member 150 has a shape of a generally rectangular pillar. The friction member 150 is inserted into the base 110 and is linearly movable therein. Further, one side of the friction member 150 is flat and contacts the stop protrusion 123. The opposite side of the friction member 150 contacts a first elastic member 161.

The first elastic member 161 comprises a coil spring. The first elastic member is inserted between the friction member 150 and the base 110 as compressed. The first elastic member elastically supports the friction member 150 toward the connecting member 120. Thus, the friction member 150 is allowed to be linearly moved by the first elastic member 161 and brought into contact with the stop protrusion 123.

The supporting member 130 has a shape of an elongated rod. Second shaft supports 131 are bilaterally formed at one end of the supporting member. The second shaft supports 111 define a space therebetween. Further, the second shaft supports 131 are oriented perpendicularly to the first shaft supports 111.

The opposite end of the connecting member 120 is oriented perpendicular to the stop protrusion 123. A plurality of sawtooth-shaped engagement grooves 124 are formed at an equal pitch at the opposite end of the connecting member. That is, the opposite end of the connecting member 120 is oriented parallel to the second shaft supports 131. Further, the opposite end of the connecting member 120 with the engagement grooves 124 formed thereon is inserted between and rotatably coupled to the second shaft supports 131. Thus, the first rotating shaft 171 and the second rotating shaft 171 become perpendicular to each other. Also, the connecting member 120 and the supporting member 130 are allowed to rotate perpendicularly to each other.

The first rotating shaft 171 and the second rotating shaft 172 may be oriented so that they can rotate at any other angle relative to each other. However, perpendicular arrangement can provide convenience to angle adjustment. Thus, in this embodiment, they are oriented perpendicularly.

The engaging member 140 is inserted into the supporting member 130 through the second shaft supports 131 and is allowed to linearly move therein.

Further, an engagement protrusion 141, which is inserted into the engagement groove 124, is formed at one side of the engaging member 140. A second elastic member 161 for elastically supporting the engaging member 140 toward the engagement grooves 124 is provided at the opposite side of the engaging member.

The engagement protrusion 141 protrudes while gradually tapering. A tip edge of the engagement protrusion is rounded, thereby allowing a smooth rotation during the rotation of the supporting member 130. Similar to the first elastic member 161, the second elastic member 162 comprises a coil spring.

The stand hinge for an electronic device 100, which is constructed as described above, is mounted to the electronic device in an insertion manner and supports the electronic device at different angles against a surface. The electronic device primarily means a portable electronic device such as a DMB terminal, PMP, electronic dictionary, MP3 player, portable terminal, etc.

As shown in FIG. 5, the electronic device comprises a main body 200, a movable body 300, a stand groove 210 and the stand hinge 100.

The movable body 300 is slidably mounted to one side of the main body 200. The stand groove 210 for inserting the stand hinge 100 therein is linearly formed at the opposite side of the main body.

The stand groove 210 is located at one edge of the opposite side of the electronic device. One end of the stand groove 210 is open. Further, the base 110, the connecting member 120 and the supporting member 130, which are linearly connected to one another, are inserted into the stand groove 210. Since the stand hinge for an electronic device 100 is linearly arranged, the electronic device can be small in size and have a simple appearance. In addition, as the one end of the stand groove 210 is open, the stand hinge for an electronic device 100 can be easily rotated out of the electronic device.

The operating processes of the stand hinge 100, which is constructed as described above, will be described below.

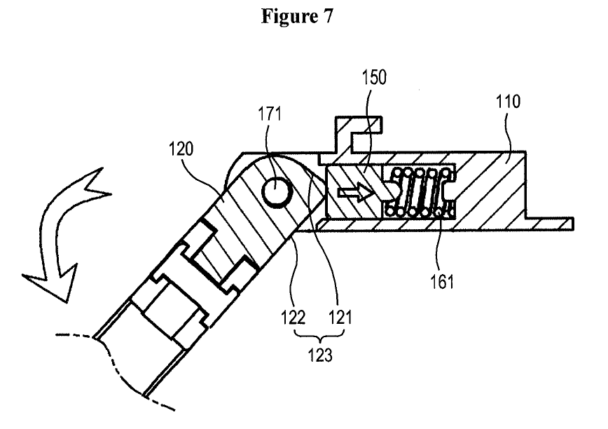

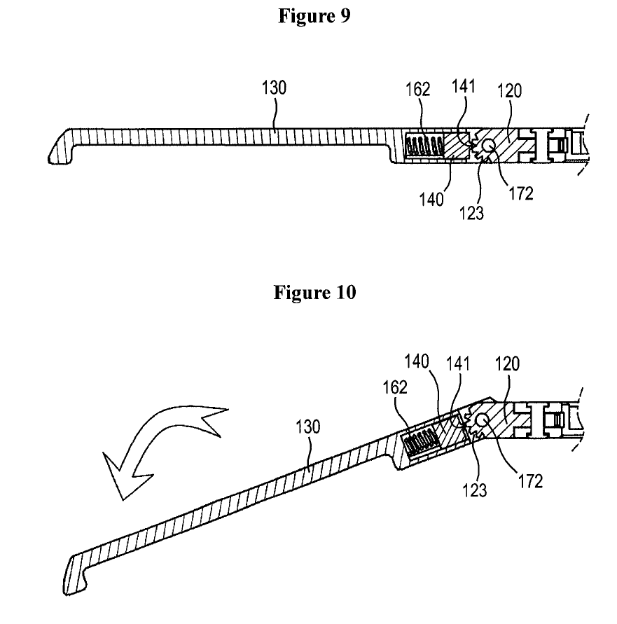

FIGS. 6 to 8 show operations of a stand hinge taken along the line A-A of FIG. 3. FIGS. 9 to 11 show operations of a stand hinge taken along the line B-B of FIG. 3. FIGS. 12 to 14 show operations of an electronic device with a stand hinge according to one embodiment of the present invention.

As shown in FIG. 6, as the sloped surface 121 with its lower side higher is in contact with the friction member 150, the connecting member 120 is subjected to a rotational force in an upward direction of FIG. 6.

As shown in FIG. 12, however, since the connecting member 120 is inserted into the stand groove 210, it becomes closely contacted to the electronic device without any rotation. In other words, the sloped surface 121 contacts the friction member 150, thereby inhibiting the connecting member 120 from being arbitrarily rotated. Accordingly, when the stand hinge 100 is not in use, it becomes closely contacted to the electronic device and is not allowed to appear outward of the electronic device.

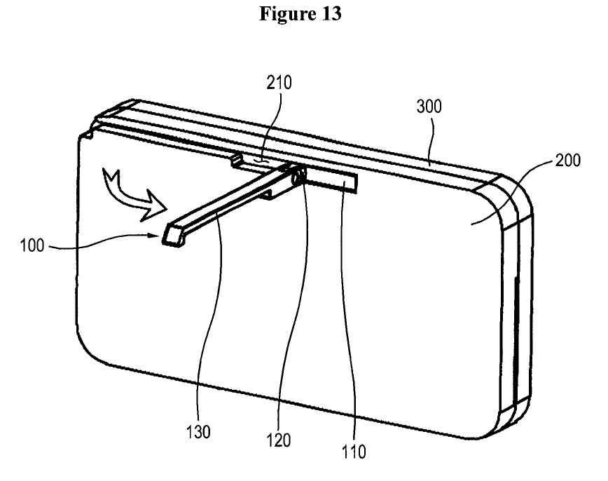

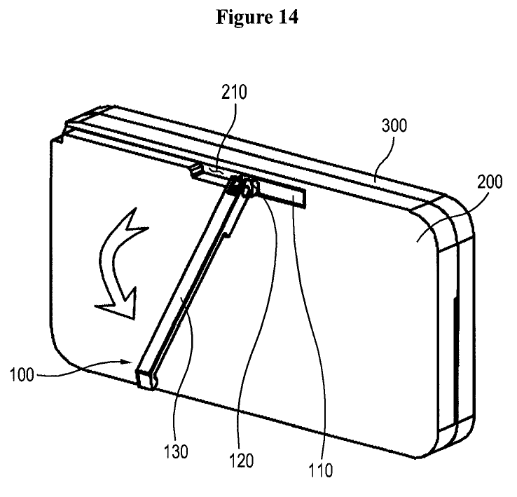

When a user wants to watch TV or movies from the electronic device, the supporting member 130, which is inserted into the stand groove 210, is pulled out and then rotated so as to be perpendicular to the main body 200. In such a case, the connecting member 120 coupled to the supporting member 130 is also rotated together therewith, as shown in FIG. 13.

As shown in FIG. 7, along with the rotation of the connecting member 120, the friction member 150 is moved backward by the sloped surface 121 while compressing the first elastic member 161. Subsequently, as the intersection between the sloped surface 121 and the straight surface 122 passes by the center of the friction member 150, the connecting member 120 automatically rotates under the expansion force of the first elastic member 161. As such, the friction member 150 semi-automatically rotates the stop protrusion 123 by means of the elastic force of the first elastic member 161, thereby providing a simple and convenient operation of the connecting member 120.

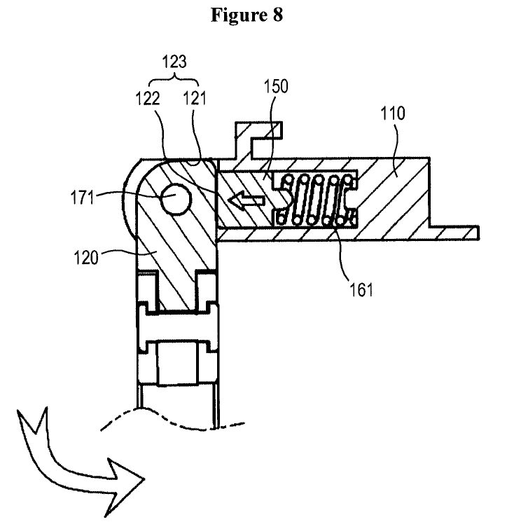

Thereafter, as shown in FIG. 8, when the straight surface 122, which is angled at an angle of about 90 degrees relative to the sloped surface 121, is contacted to the friction member 150 (i.e., when the connecting member 120 and the friction member 150 are perpendicular to each other), the connecting member 120 stops its rotation. Thus, as shown in FIG. 13, the supporting member 130 projects backward of the electronic device. In such a case, as shown in FIG. 9, with the engagement protrusion 141 inserted into one of the engagement grooves 124, the supporting member 130 is fixed relative to the connecting member 120 as being parallel thereto.

As shown in FIGS. 10 and 14, as the supporting member 130 is rotated downwardly, the engaging member 140 is moved toward the supporting member 130 while compressing the second elastic member 162.

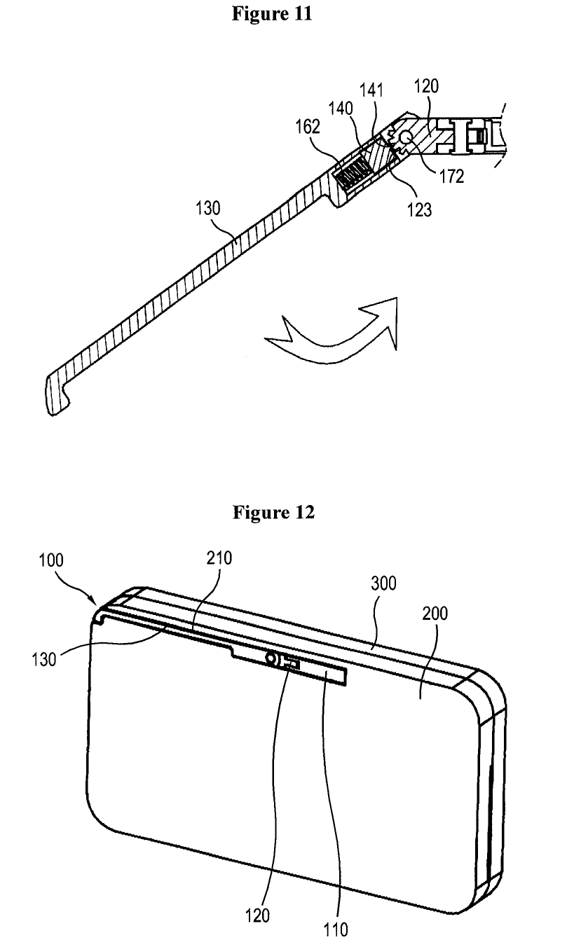

Thereafter, as the supporting member 130 is continued to rotate downwardly, the engagement protrusion 141 is inserted into another engagement groove 124 under the expansion force of the second elastic member 162, as shown in FIG. 11. Then, the supporting member 130 is locked by the engagement protrusion 141 and is inhibited from being further rotated.

Accordingly, the supporting member 130 is allowed to stepwise rotate as the engagement protrusion 141 is inserted into the engagement grooves 124. It is possible to stand the electronic device at different angles by varying the number and pitch of the engagement grooves 124.

According to the above-described constitution, the connecting member 120 and the supporting member 130 of the stand hinge 100 are rotatable in two different directions. Thus, the stand hinge 100 can stand the electronic device at different angles.

Further, since the connecting member 120 and the supporting member 130 are rotatable perpendicularly to each other, the stand hinge 100 provides easy angle adjustment and convenient use.

Also, since the stand hinge 100 can be linearly inserted into the stand groove 210, the electronic device has a simple structure and becomes small in size.

A stand hinge of the present invention and an electronic device using the same should not be limited to the above-described embodiments and may be embodied in various manners within the scope of the subject matter of the present invention.

1. A stand hinge for an electronic device, comprising:
a connecting member hinge-jointed to an electronic device to rotate in a first direction; and
a supporting member for supporting the electronic device against a surface, the supporting member being hinge-jointed to the connecting member to rotate in a second direction different from the first direction.

2. The stand hinge of claim 1, wherein the connecting member is rotated perpendicularly to the electronic device, and
wherein the supporting member is rotated perpendicularly to a rotating direction of the connecting member.

3. The stand hinge of claim 1, wherein the connecting member or the supporting member is semi-automatically rotated.

4. The stand hinge of claim 1, wherein the connecting member or the supporting member is stepwise rotated for an angle adjustment.

5. The stand hinge of claim 3, wherein the stand hinge further comprises a base
wherein the connecting member is hinge-jointed to the base,
wherein a stop protrusion is formed at one end of the connecting member hinge-jointed to the base to semi-automatically rotate, and
wherein a friction member and an elastic member are inserted into the base, the friction member being in contact with the stop protrusion at one side thereof to restrict a rotation of the connecting member, the elastic member being in contact with an opposite side of the friction member to apply an elastic force to the friction member.

6. The stand hinge of claim 5, wherein one surface of the stop protrusion is in contact with the friction member to prevent the rotation of the connecting member, and
wherein the other surface of the stop protrusion adjoining the one surface is brought into contact with the friction member after the rotation of the connecting member to stop the rotation of the connecting member.

7. The stand hinge of claim 4, wherein an engagement groove is formed at an opposite end of the connecting member joined to the supporting member to stepwise rotate, and
wherein an engaging member and an elastic member are inserted into the supporting member, the engaging member being formed at one side thereof with an engagement protrusion being inserted into the engagement groove, the elastic member being in contact with an opposite side of the engaging member to elastically support the engaging member.

8. An electronic device, comprising:
a stand hinge for supporting the electronic device,
the stand hinge including:
a connecting member hinge-jointed to an electronic device to rotate in a first direction; and
a supporting member for supporting the electronic device against a surface, the supporting member being hinge-jointed to the connecting member to rotate in a second direction different from the first direction,
wherein a stand groove to which the stand hinge is inserted is formed at the electronic device.

9. The electronic device of claim 8, wherein the electronic device further comprises a base inserted into the stand groove of the electronic device, and
wherein the stand groove is linearly formed such that the base, the connecting member and the supporting member are inserted therein.

10. The electronic device of claim 8, wherein:
the stand hinge further comprises a base;
the connecting member is hinge-jointed to the base;
a stop protrusion is formed at one end of the connecting member hinge-jointed to the base to semi-automatically rotate; and
a friction member and an elastic member are inserted into the base, the friction member being in contact with the stop protrusion at one side thereof to restrict a rotation of the connecting member, the elastic member being in contact with an opposite side of the friction member to apply an elastic force to the friction member.

11. The electronic device of claim 10, wherein:
one surface of the stop protrusion is in contact with the friction member to prevent the rotation of the connecting member; and
the other surface of the stop protrusion adjoining the one surface is brought into contact with the friction member after the rotation of the connecting member to stop the rotation of the connecting member.

12. The stand hinge of claim 2, wherein the connecting member or the supporting member is semi-automatically rotated.

13. The stand hinge of claim 12, wherein:
the stand hinge further comprises a base;
the connecting member is hinge-jointed to the base;
a stop protrusion is formed at one end of the connecting member hinge-jointed to the base to semi-automatically rotate; and
a friction member and an elastic member are inserted into the base, the friction member being in contact with the stop protrusion at one side thereof to restrict a rotation of the connecting member, the elastic member being in contact with an opposite side of the friction member to apply an elastic force to the friction member.

14. The stand hinge of claim 13, wherein:
one surface of the stop protrusion is in contact with the friction member to prevent the rotation of the connecting member; and
the other surface of the stop protrusion adjoining the one surface is brought into contact with the friction member after the rotation of the connecting member to stop the rotation of the connecting member.

15. The stand hinge of claim 2, wherein the connecting member or the supporting member is stepwise rotated for an angle adjustment.

16. The stand hinge of claim 7, wherein:
the engagement groove comprises a plurality of sawtooth-shaped engagement grooves; and/or
the elastic member comprises a coil spring.

17. The stand hinge of claim 1, further comprising a base, and wherein:
the connecting member is hinge-jointed to the base;
a stop protrusion is formed at one end of the connecting member hinge-jointed to the base to semi-automatically rotate; and
a friction member and an elastic member are inserted into the base, the friction member being in contact with the stop protrusion at one side thereof to restrict a rotation of the connecting member, the elastic member being in contact with an opposite side of the friction member to apply an elastic force to the friction member.

18. The stand hinge of claim 17, wherein:
one surface of the stop protrusion is in contact with the friction member to prevent the rotation of the connecting member; and
the other surface of the stop protrusion adjoining the one surface is brought into contact with the friction member after the rotation of the connecting member to stop the rotation of the connecting member.

19. An electronic device comprising the stand hinge of claim 1, wherein:
the stand hinge further comprises a base fixedly mounted or integrally formed to the electronic device; and
the connecting member is hinge-jointed to the base.

20. An electronic device comprising the stand hinge of claim 1 and a stand groove linearly formed such that the connecting member and the supporting member are inserted therein.
